(19) United States
(12) Patent Application Publication
(10) Pub. No.: US 2018/0166402 A1
(43) Pub. Date: Jun. 14, 2018

(54) INTEGRATED EFUSE

(71) Applicant: GLOBALFOUNDRIES INC., GRAND CAYMAN (KY)

(72) Inventors: Viraj SARDESAI, Malta, NY (US); William HENSON, Malta, NY (US); Domingo FERRER LUPPI, Malta, NY (US); Scott ALLEN, Poughquag, NY (US); Emre ALPTEKIN, Albany, NY (US)

(73) Assignee: GLOBALFOUNDRIES INC., GRAND CAYMAN (KY)

(21) Appl. No.: 15/373,898

(22) Filed: Dec. 9, 2016

(51) Int. Cl. H01L 23/62; H01L 21/768; H01L 23/528; H01L 23/522; H01L 23/532

(52) U.S. Cl. CPC H01L 23/62; H01L 21/76877; H01L 21/76843; H01L 23/53252; H01L 23/5283; H01L 23/5228; H01L 21/76804

(57) ABSTRACT

A semiconductor device includes a metal thin film such as an eFUSE or a precision resistor above and laterally displaced from an interconnect structure. A first dielectric layer is disposed over the interconnect structure and optionally under the metal thin film, and is adapted to prevent etching of the interconnect structure during patterning of the metal thin film. Contacts to the metal thin film and the interconnect are made through a second dielectric layer that is disposed over the metal thin film and over the interconnect.

### BACKGROUND

The present application relates generally to semiconductor devices, and more specifically to semiconductor devices having electronically programmable fuses (eFUSEs) and methods of making the same.

Electronically programmable fuses (eFUSEs) are used in integrated circuits (ICs) as passive devices to program circuits for different functions. To reduce manufacturing costs, transistors and other elements on a chip can be initially connected with other transistors, memory arrays, and the like, including a linked component for programming. After a standardized semiconductor chip is complete, the chip can be customized using input data (i.e., programmed).

Programming using an eFUSE typically involves passing a large electrical current through the eFUSE, which breaks the eFUSE structure resulting in a permanent electrical open. EFUSEs can also be configured to electrically repair failures within an IC product. EFUSEs utilize electromigration for both forming open circuits and for repairing.

During programming, for a given applied voltage, if the eFUSE resistance (R) is too high, the current can be insufficient to blow the fuse and the device functionality will not be achieved as intended. Thus, the electrical connections to an as-manufactured eFUSE are desirably robust to allow efficient and effective programming of the integrated circuit.

In many device architectures, electrical connections to the eFUSEs and other IC elements are formed simultaneously. Geometric effects, etch selectivities, and other factors contribute to the challenge of successfully integrating eFUSE architectures with other IC architectures. For example, during the simultaneous etching of eFUSE contacts and transistor trench silicide contacts, over-etching (or gouging) of the eFUSE metal thin film has been observed.

### SUMMARY

There is a need for improved structures and methods for integrating eFUSEs and other metal thin film architectures into IC process flows. In accordance with embodiments of the present application, a semiconductor device includes an interconnect structure, a first dielectric layer disposed over an exposed surface of the interconnect structure, a patterned metal thin film disposed optionally over the first dielectric layer and laterally displaced from the interconnect structure, and a second dielectric layer disposed over the patterned metal thin film and over an exposed surface of the second dielectric layer laterally displaced from the patterned metal thin film, i.e., over the interconnect structure.

A method of forming a semiconductor device comprises forming a first dielectric layer over an exposed surface of an interconnect structure, forming a patterned metal thin film laterally displaced from the interconnect structure, and forming a second dielectric layer over the patterned metal thin film and over the interconnect structure, i.e., directly over a portion of the first dielectric layer, such that a thickness and an etch rate of the second dielectric layer over the patterned metal thin film differs by less than 25% from a combined thickness and combined etch rate of the first dielectric layer and the second dielectric layer over the interconnect structure.

A first via opening is etched through the second dielectric layer to expose a top surface of the metal thin film, and a second via opening is etched through the second dielectric layer to expose a top surface of the interconnect structure. A first contact is formed within the first via opening in electrical contact with the patterned metal thin film, and a second contact is formed within the second via opening in electrical contact with the interconnect structure. During etching, an average etch rate of the second dielectric layer and the first dielectric layer over the interconnect structure is within 25% of an average etch rate of the second dielectric layer over the patterned metal thin film.

A semiconductor device comprises a first dielectric layer disposed over an exposed surface of an interconnect structure, a patterned metal thin film laterally displaced from the interconnect structure, and a second dielectric layer disposed over the patterned metal thin film and over an exposed surface of the first dielectric layer laterally displaced from the patterned metal thin film. A first contact extends through the second dielectric layer and is in electrical contact with the patterned metal thin film. A second contact extends through the second dielectric layer and the first dielectric layer and is in electrical contact with the interconnect structure, where a thickness of the second dielectric layer over the patterned metal thin film differs by less than 25% from a combined thickness of the first dielectric layer and the second dielectric layer over the interconnect structure.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a cross-sectional schematic view of a portion of a comparative semiconductor device including an eFUSE metal thin film and trench silicide contact;

FIG. 2 is a transmission electron microscope (TEM) micrograph of the metal thin film architecture of FIG. 1 prior to contact formation;

FIG. 3 is a TEM micrograph showing gouging of the metal thin film of FIG. 1;

FIG. 4 is a flow chart of a process for co-integrating metal thin films and interconnect structures such as trench silicide structures disposed on different levels of a chip according to various embodiments;

FIG. 5A is a cross-sectional schematic view of a semiconductor device architecture following a trench silicide process;

FIG. 5B shows the formation of a trench silicide capping layer over the structure of FIG. 5A;

FIG. 5C shows the formation of a metal thin film over the trench silicide capping layer;

FIG. 5D depicts a patterned metal thin film and partially etched trench silicide capping layer;

FIG. 5E shows the formation of a further capping layer over the patterned metal thin film and the trench silicide capping layer;

FIG. 5F shows a planarized contact level dielectric layer disposed over the structure of FIG. 5E;

FIG. 5G shows the formation of contact vias through the contact level dielectric layer and capping layer(s) to the patterned metal thin film in a first region of the semiconductor device, and to the trench silicide interconnect structures in a second region of the semiconductor device;

FIG. 5H depicts the formation of interconnect structures within the contact vias;

FIG. 6 is a cross-sectional schematic view of a portion of a semiconductor device including an eFUSE metal thin film and trench silicide contact according to various embodiments;

FIG. 7 is a TEM micrograph of the metal thin film architecture of FIG. 6 prior to contact formation according to various embodiments; and

FIG. 8 is a TEM micrograph corresponding to the structure of FIG. 6 showing a contact region disposed over an eFUSE metal thin film.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

It will be appreciated that the disclosed methods and structures may be used in conjunction with a variety of semiconductor device architectures to successfully incorporate metal thin film structures into integrated circuit process flows. Example device architectures include, but are not limited to, memory devices, resistors, capacitors, diodes, rectifiers, and other semiconductor devices, such as thyristors, metal-semiconductor field effect transistors, metal-oxide-semiconductor field effect transistors (MOSFETs), fin field effect transistors (FinFETS), Schottky barrier MOSFETS and bipolar junction transistors. Further, while various embodiments are described in the context of an eFUSE metal thin film, it will be appreciated that the metal thin film structures may be configured as other conductive structures, such as precision resistors.

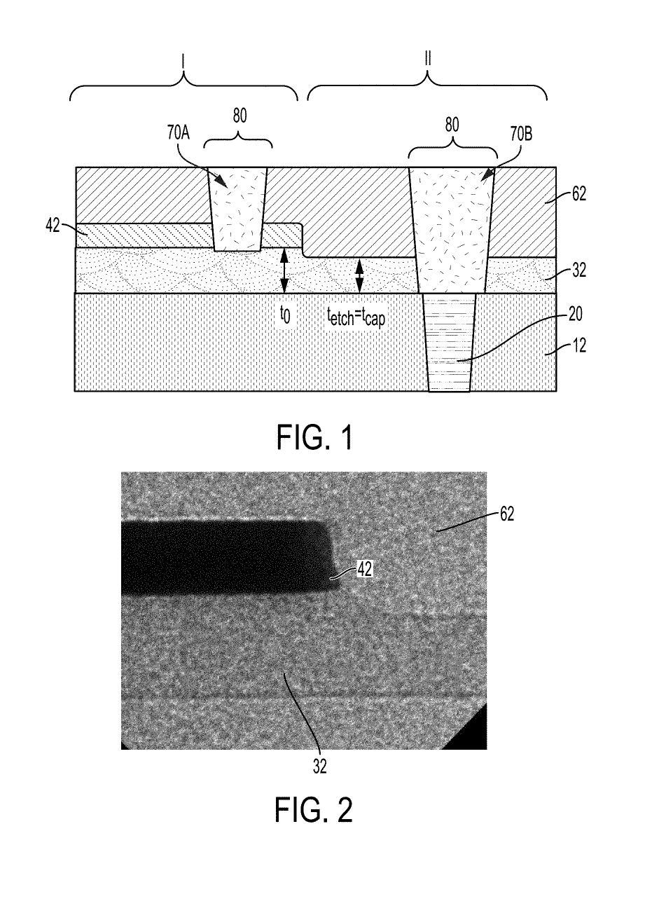

FIG. 1 is a schematic cross-sectional view of a portion of a comparative semiconductor device. In the illustrated device, an interconnect structure 20 extends though interlayer dielectric 12 to make electrical contact with underlying device structures (not shown). Interconnect structure 20 may comprise any suitable conductive structure such as a trench silicide (TS) contact as known to those skilled in the art.

A trench silicide capping layer 32 is deposited over the interlayer dielectric 12 and exposed portions of the interconnect structure 20. In such a comparative architecture, a metal thin film 42 is then deposited over the trench silicide capping layer 32 and patterned using lithography and etching techniques to define a shape of the eFUSE. The etching of metal thin film 42 may etch portions of trench silicide capping capping layer that are not covered by metal thin film 42 such that a thickness thereof (t_{etch}) may be less than a thickness (t₀) of the trench silicide capping layer 32 directly underneath metal thin film 42 as is shown in FIG. 1.

After etching the metal thin film 42, a contact level dielectric layer 62 is deposited over the patterned metal thin film 42 and over exposed portions of the trench silicide capping layer 32. A cross-sectional transmission electron microscope (TEM) micrograph of an exemplary device structure after patterning the metal thin film 42 and depositing the contact level dielectric layer 62 is shown in FIG. 2.

Referring again to FIG. 1, within a first region (I) of the device, via openings 70A are created in the contact level dielectric layer 62 to expose the metal thin film 42. Within a second region (II) of the device, via openings 70B are created in contact level dielectric layer 62 and in underlying capping layer 32 to expose the interconnect structure 20.

A first etch chemistry may be used to create openings 70A and 70B in the contact level dielectric layer 62, while additional etching using a second etch chemistry different from the first etch chemistry may be used to remove capping layer 32 from within opening 70B to expose a top surface of the interconnect structure 20. However, because the etch chemistry used to etch the capping layer 32 is typically not selective to the metal thin film 42, etching of the capping layer 32 in the via opening 70B within the second region (II) to expose interconnect structure 20 may to a certain extent undesirably cause etching of the metal thin film 42 and thus cause gouging of the metal thin film 42 within via opening 70A in the first region (I). Metal thin film 42 is formed as part of the eFUSE in the first region (I).

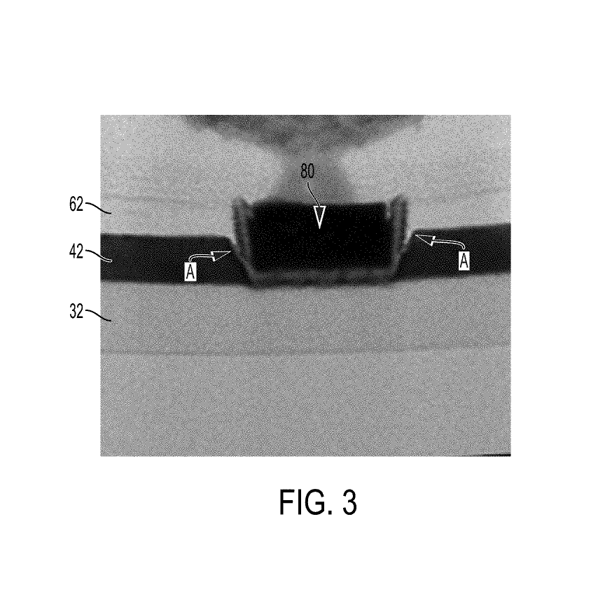

After defining the via openings 70A, 70B, interconnect structures 80, which are also referred to as a diffusion contacts (CA), are formed within the via openings. A TEM micrograph showing interconnect structure 80 within the first region (I), extending through contact level dielectric layer 62, and making contact with metal thin film 42 is shown in FIG. 3. Significant gouging of the metal thin film 42 is evident due to the etch processes used to remove capping layer 32, which is done in order to ensure completely open vias 70B in the second region that expose interconnect structure 20. Consequently, the via opening etch could have removed a significant portion, and in some cases more than 90% of the thickness of the metal thin film 42 that is in the first region (I).

Gouging of the metal thin film 42 may significantly decrease the interfacial area and correspondingly increase the electrical resistance between the interconnect structure 80 and the metal thin film 42. In particular, if the metal thin film 42 is etched completely through, a bottom surface of the interconnect structure 80 will contact capping layer 32 rather than metal thin film 42, and only sidewall surfaces of the interconnect structure 80 will make electrical contact with the metal thin film 42.

Further, as also seen with reference to FIG. 3, material from contact level dielectric layer 62 may be disposed between interconnect structure 80 and metal thin film 42 along the sidewalls of the interconnect structure 80, further contributing to the increase in resistance between the conductive elements. Arrows (A) highlight material from the contact level dielectric layer 62 that is disposed between the interconnect structure 80 and the metal thin film 42.

Disclosed herein is a modified structure and associated method that facilitates co-integration of metal thin films, such as metal thin films used to form eFUSEs, and interconnect structures (e.g., trench silicide structures) disposed on different levels of a chip according to certain embodiments. The architecture and the corresponding process flow enable lithography, etching and stripping of a portion of a metal thin film to form, for example, an eFUSE or precision resistor structure. Also, the modified architecture enables a robust via opening process, whereby contact vias to top surfaces of both the metal thin film and the adjacent interconnect structure may be formed without gouging of the metal thin film.

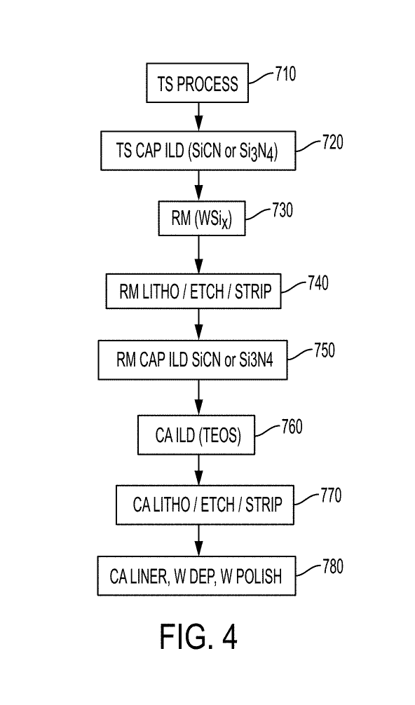

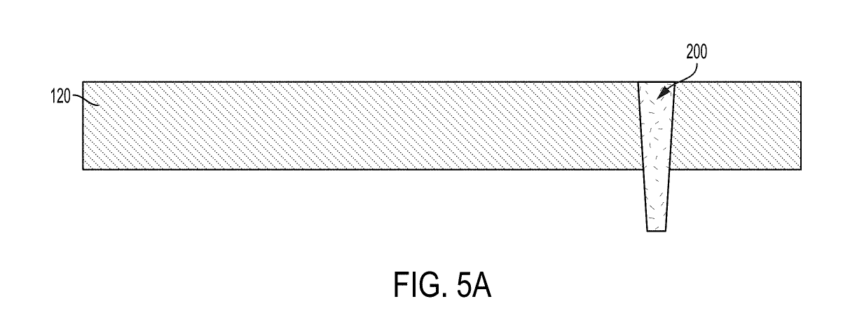

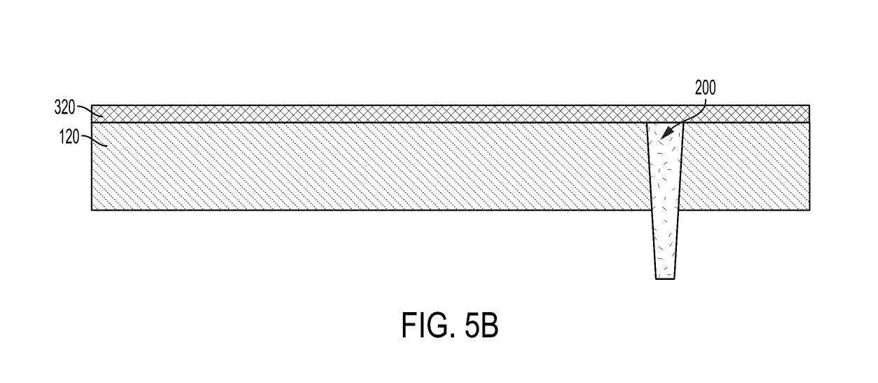

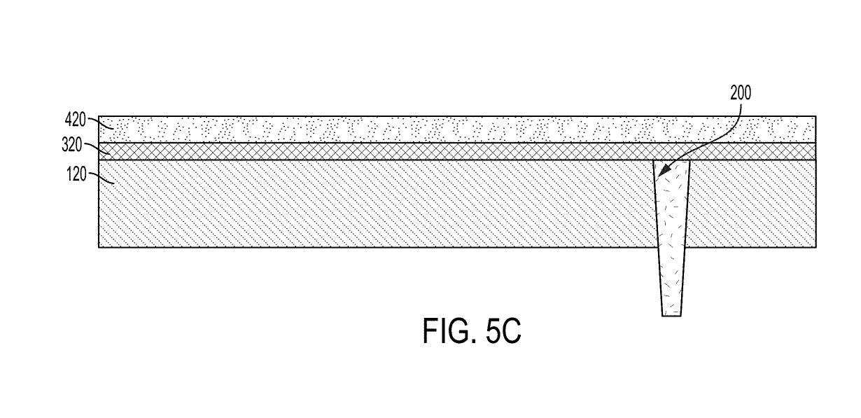

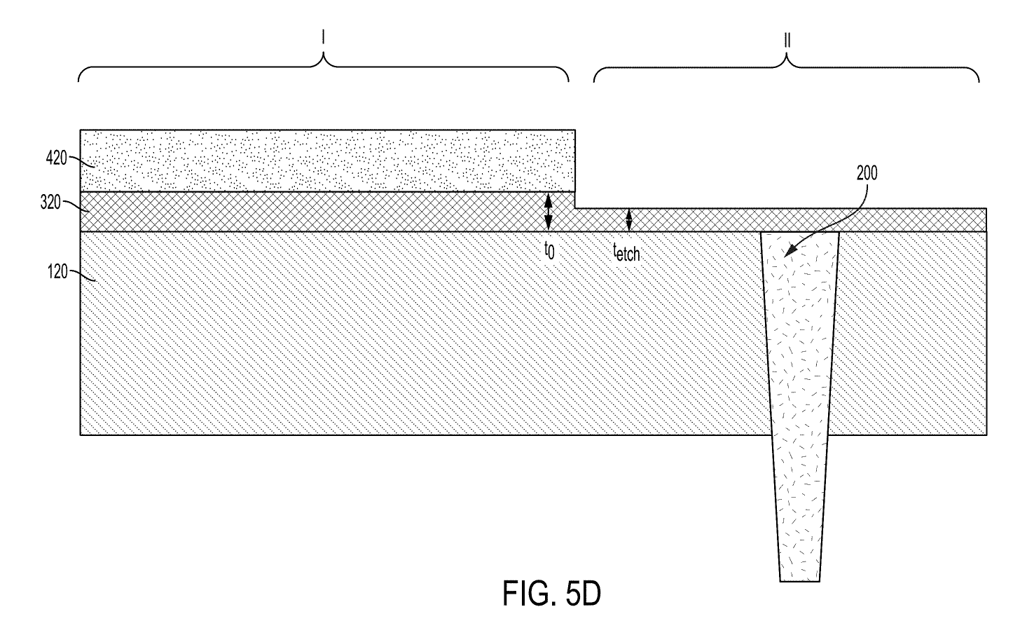

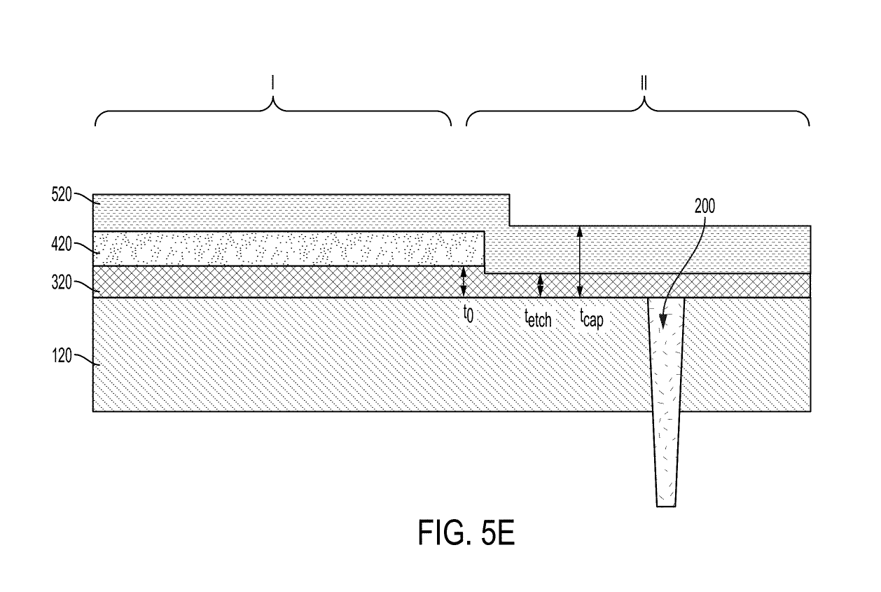

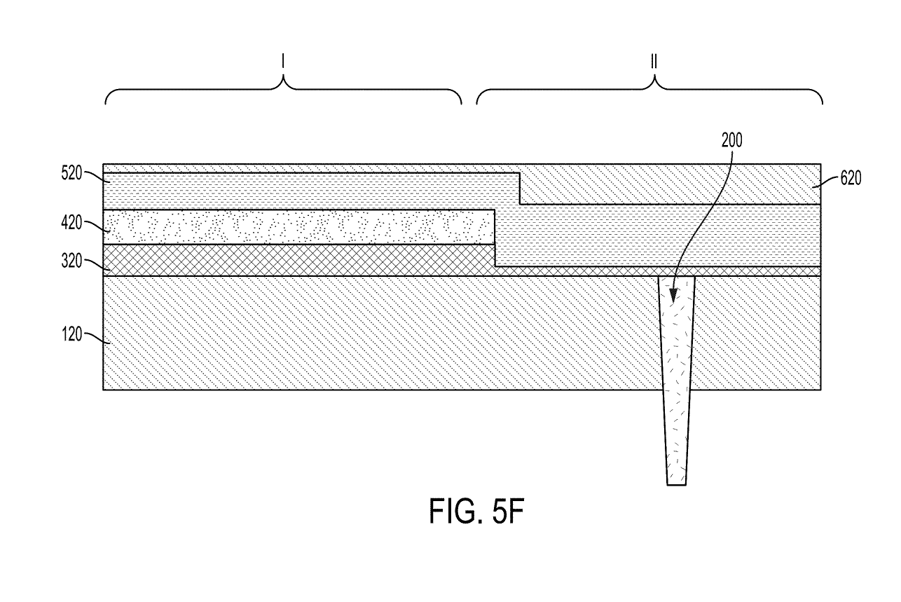

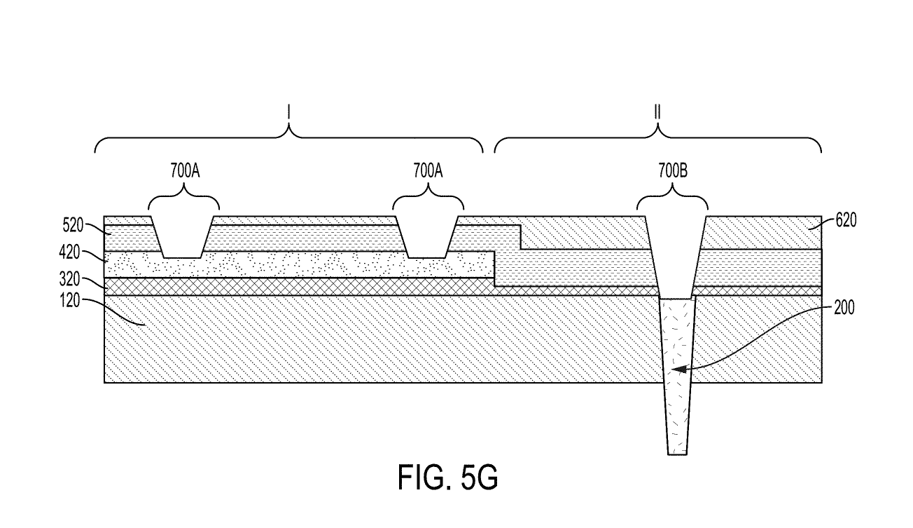

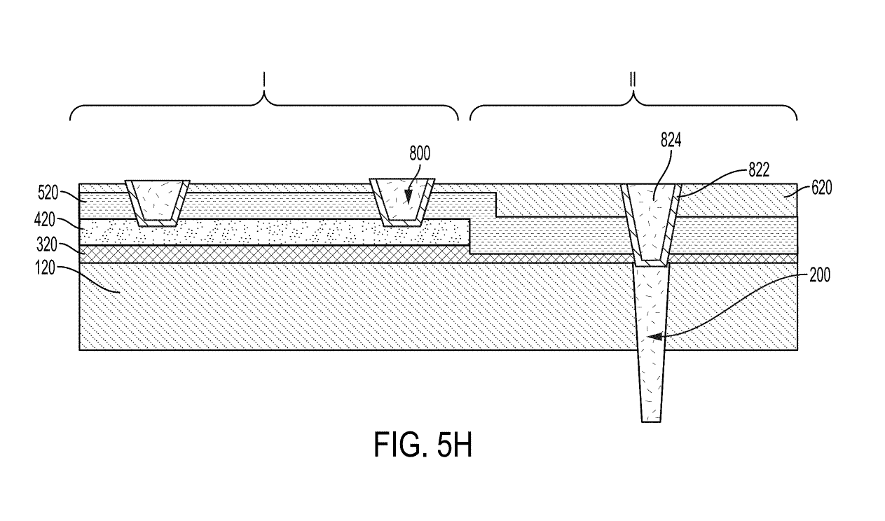

An exemplary process, which incorporates the use of a first capping layer (TS capping layer) above the interconnect structure and optionally disposed below the metal thin film (RM) and a second capping layer (RM capping layer) above the metal thin film and over the interconnect structure is summarized in the flow chart of FIG. 4, while various steps of the exemplary process are illustrated schematically in FIGS. 5A-5H.

Illustrated in FIG. 5A is a cross-sectional schematic view of a semiconductor device architecture following a trench silicide process, corresponding to step 710 in FIG. 4, where interconnect structure 200 is disposed within interlayer dielectric 120. FIG. 5B shows the formation of a first capping layer 320 (TS capping layer) over the planarized structure shown in FIG. 5A, corresponding to step 720 in FIG. 4. In certain embodiments, a blanket capping layer 320 is deposited over exposed surfaces of the interlayer dielectric 120 and the interconnect structure 200.

The first capping layer 320 may comprise a dielectric material such as, for example, silicon nitride (Si₃N₄) or silicon carbon nitride (SiCN). The first capping layer 320 is adapted to inhibit the diffusion of metal atoms such as copper, and also has a low leakage current. Thus, the first capping layer 320 can be used as a diffusion barrier between metal-containing structures (e.g., lines and vias) and dielectric layers to prevent metal atom diffusion into the dielectric materials. The first capping layer 320 can also be used as a passivation layer or etch stop and can protect the underlying interconnect structure 200 during later processing steps.

A variety of methods can be used to form the first capping layer 320, including plasma enhanced chemical vapor deposition (PECVD) (e.g., using SiH₄, CH₄ and NH₃ as precursor gases) or high density plasma chemical vapor deposition (HDP CVD) (e.g., using SiH₄, C₂H₂ and N₂ as precursor gases). The thickness of the as-deposited first capping layer 320 may range from 5 to 35 nm, e.g., 5, 10, 15, 20, 25, 30 or 35 nm, including ranges between any of the foregoing values.

In various embodiments, the first capping layer 320 is preferably thin, e.g., thinner than the capping layer 32 used in the comparative layout (FIG. 1), but is thick enough to protect the underlying interconnect structure 200, as well as interlayer dielectric 120 during subsequent lithography, etching and stripping of the metal thin film formed adjacent to the interconnect structure, e.g., on top of capping layer 320. First capping layer 320 has an as-deposited thickness (t₀).

Then, as illustrated in FIG. 5C, a metal thin film 420 is formed over the first capping layer 320, corresponding to step 730 in FIG. 4. Referring to FIG. 5D, corresponding to step 740 of FIG. 4, using lithography and etching techniques, the metal thin film 420 is patterned to form, for example, an eFUSE or precision resistor geometry within a first region (I) of the device. Within a second region (II) of the device laterally adjacent to the first region (1), the metal thin film 420 is removed, exposing the first capping layer 320, which may be partially removed during removal of metal thin film 420 within the second region (II).

As a result of the etch used to pattern the metal thin film 420, the post-etch thickness (t_{etch}) of the first capping layer 320 adjacent to the metal thin film 420 may be less than the as-deposited thickness (t₀). For instance, the thickness of the first capping layer 320 may be decreased by 10 to 50%, e.g., 10, 20, 30, 40 or 50%, including ranges between any of the foregoing values. The thickness reduction may be dependent on one or more of the initial thickness of the metal thin film 420, the selectivity of the etch, the composition and density of the first capping layer 320, and the total etch time used to pattern the metal thin film 420. In any event, the interconnect structure 200 shall still be protected by the remaining portions of the first capping layer 320.

The metal thin film 420 (also referred to as RM) may include a metal silicide such as tungsten silicide, WSiₓ. The metal thin film 420 can have a thermal coefficient of resistance (TCR) variability of ±5×10⁻⁶/° C. The thickness of the metal thin film 420 may range from 10 to 40 nm, e.g., 10, 15, 20, 25, 30, 35 or 40 nm, including ranges between any of the foregoing values, and may be determined by the desired resistance of the metal thin film and/or the desired fuse blow voltage.

During etching to pattern the metal thin film 420, it is desirable to avoid etching the interconnect structure 200. In various embodiments, first capping layer 320 protects the underlying interconnect structure 200 from exposure to the etch chemistry used to remove the metal thin film. Although the first capping layer 320 may be partially etched during a selective etching process, the first capping layer 320 is adapted to protect the underlying interconnect structure 200, as well as interlayer dielectric 120.

Then, referring to FIG. 5E, corresponding to step 750 in FIG. 4, after etching the metal thin film 420 to define the eFUSE geometry, a second capping layer 520 (RM capping layer) is formed over the patterned metal thin film 420, e.g., directly over the metal thin film 420, within the first region (I), and over the first capping layer 320, e.g., directly over the first capping layer 320, within the second region (II).

Thus, the second capping layer 520 is disposed over the patterned metal thin film 420 and over the interconnect structure 200, while the first capping layer 320 is disposed over the interconnect structure 200 and optionally disposed under the patterned metal thin film 420. The thickness of the as-deposited second capping layer 520 may range from 5 to 35 nm, e.g., 5, 10, 15, 20, 25, 30 or 35 nm, including ranges between any of the foregoing values.

In various embodiments, the total thickness (t_{cap}) of second capping layer 520 and first capping layer 320 within the second region (II), i.e., over interconnect structure 200, is comparable to the thickness (t_{cap}) of the capping layer 32 within the second region (II), i.e., over the interconnect structure 20 in the comparative architecture of FIG. 1. In various embodiments, the average etch rate of the second capping layer 520 and the first capping layer 320 within the second region (II) is comparable to the average etch rate of the capping layer 32 within the second region (II) in FIG. 1. This parity in capping layer thickness over the interconnect structure and/or the average etch rate of the layer(s) over the interconnect structure advantageously allows etching processes used for the comparative structure to be used for the inventive structure with minimal modification. By way of example, the total thickness (t_{cap}) of second capping layer 520 and the first capping layer 320 within the second region (II) may range from 10 to 70 nm, e.g., 10, 20, 30, 40, 50, 60 or 70 nm, including ranges between any of the foregoing values.

Second capping layer 520 may be formed in a manner as described above in connection with the formation of first capping layer 320. Second capping layer 520 may comprise a dielectric material such as silicon nitride (e.g., Si₃N₄) or silicon carbon nitride (SiCN), for example. The material used to form second capping layer 520 may be the same as the material used to form first capping layer 320. According to exemplary embodiments, second capping layer 520 and first capping layer 320 each comprise Si₃N₄ or SiCN, which can simplify the process for etching via openings through these layers as described further below.

As shown in FIG. 5F (step 760), a contact level dielectric layer 620 is deposited over the second capping layer 520 and planarized. Contact level dielectric layer 620 may comprise silicon dioxide or silicon oxynitride, for example. The contact level dielectric layer 620 may be formed by CVD using, for example, tetraethylorthosilicate (TEOS) as a precursor and may comprise silicon dioxide (SiO₂). The thickness of the contact level dielectric layer 620 may range from 50 to 150 nm, e.g., 50, 100 or 150 nm, including ranges between any of the foregoing values. In various embodiments, the material used to form contact level dielectric layer 620 is different from the material used to form first capping layer 320 and second capping layer 520 such that, for example, the contact level dielectric layer 620 etches at a rate that is greater than the etch rate of the first capping layer 320 and the second capping layer 520 during etching of via openings. An optional chemical mechanical polishing (CMP) step may be used to planarize the contact level dielectric layer 620, e.g., prior to contact patterning.

At step 770, via openings 700A are patterned and etched through contact level dielectric layer 620 and second capping layer 520 to expose metal thin film 420 within the first region (I) of the device, and via openings 700B are patterned and etched through contact level dielectric layer 620, second capping layer 520, and first capping layer 320 to expose interconnect structure 200 within the second region (II) of the device. As explained in further detail below, gouging of the metal thin film 420 may be decreased as a result of the contact via etch, such that the via openings 700A extend through less than 50%, sometimes much less, of a thickness of the patterned metal thin film 420 within first region (I) (FIG. 5G).

In contrast to the comparative structure, the formation of via openings 700A in the first region (I) and the formation of via openings 700B in the second region (II) each involves etching through contact level dielectric layer 620 as well as at least second capping layer 520. According to certain embodiments, the creation of vias openings 700A, 700B within the first and second regions may be performed simultaneously.

The via openings 700A, 700B may be formed using photolithography and etch processes known to those skilled in the art. For example, an etch mask such as a layer of photoresist (not shown) can be deposited on the upper surface of the contact level dielectric layer 620, exposed to a pattern of radiation, and then developed using a photoresist developer.

According to various embodiments, the etch step used to form via openings 700A, 700B can comprise a single etch step or plural etch steps. In a multi-step process, etching of the contact level dielectric layer 620 in both the first region (I) and the second region (II) can be performed using a first etch step. The first etch step may comprise reactive ion etching, for example, and can be performed using a suitable etch chemistry, such as a mixture of ammonia (NH₃) and nitrogen trifluoride (NF₃), or CF₄ and O₂ mixed with H₂ and N₂ gases. In certain embodiments, a gas mixture comprising from a 1:1 molar ratio to a 3:1 molar ratio of ammonia to nitrogen trifluoride can be used.

After etching through the contact level dielectric layer 620 in a first etch step, etching of the second capping layer 520 within the first and second regions and etching of the first capping layer 320 within the second region (II) can be performed using a second etch step. For instance, the second etch step may comprise reactive ion etching or inductively coupled plasma (ICP) etching of via openings using a suitable chemistry such as, for example, a NF₃-based etch chemistry (e.g., a mixture of NF₃ and O₂ or a mixture of NF₃ and Ar). In various embodiments, the average etch rate of the layers disposed over the metal thin film is comparable to the average etch rate of the layers disposed over the interconnect structure. As used herein, “comparable” values, such as comparable etch rates or comparable thicknesses, differ by less than 25%, e.g., by 0, 5, 10, 15, 20 or 25%, including ranges between any of the foregoing values.

In various embodiments, the composition and/or the density of the second capping layer 520 over the metal thin film 420 is substantially equal to the composition and/or the density of the first capping layer 320 over the interconnect structure 200. By using a diffusion barrier 320 over the interconnect structure 200 that is thinner than the diffusion barrier 32 in the comparative architecture, in various embodiments the thickness of the second capping layer 520 over the metal thin film is comparable to the total thickness of the second capping layer 520 and the first capping layer 320 over the interconnect structure. That is, the thickness of the second capping layer 520 to be etched to form openings 700A is comparable to the combined thickness of the second capping layer 520 and the first capping layer 320 to be etched to form openings 700B.

Because the average etch rate (and thickness) of the second capping layer 520 within the first region (I) of the device is comparable to the average etch rate (and thickness) of capping layers 520, 320 within the second region (II) of the device, an etch process effective to remove the capping layers within the second region and expose the interconnect structure 200 is also effective to remove the second capping layer 520 within the first region and expose the metal thin film 420 without over-etching, or at least not significantly over-etching, the metal thin film, and thus minimizing the etching and concomitant gouging or punch through of the metal thin film 420 (eFUSE). Applicant has discovered that the foregoing can be achieved by limiting the etch rate and thickness differences between the second capping layer 520 within the first region (I) and the first and second capping layers 320, 520 within the second region (II) to 25% or less.

In contrast, the thickness of contact level dielectric layer 62 over patterned metal thin film 42 within the first region (I) of the comparative structure is substantially less than the combined thickness of contact level dielectric layer 62 and trench silicide capping layer 32 over the interconnect structure 20 within the second region (II). Thus, etching of via openings within the comparative architecture typically results in excess etching of the patterned metal thin film 42 during etching of the trench silicide capping layer 32.

FIG. 5H (step 780) depicts the formation of interconnect structures 800 within the via openings 700A, 700B in each of the first region (I) and second region (II). In various embodiments, interconnect structures 800, which are also referred to as diffusion contacts (CA), include a barrier layer 882 and contact metallization 824. The barrier layer 822 may include tantalum, titanium tantalum nitride, titanium nitride, or a combination thereof. For instance, the barrier layer 822 may include a Ta layer and a TaN layer. Contact metallization 824 may comprise tungsten. Other metals that are suitable for the contact metallization 824 include, but are not limited to, copper (Cu), titanium (Ti), tantalum (Ta), nickel (Ni), cobalt (Co), silver (Ag), aluminum (Al), platinum (Pt), gold (Au) and alloys thereof.

A CMP step can be used to remove excess barrier layer and contact metallization materials from above a top surface of the contact level dielectric layer 620 to form, in certain embodiments, a global planarized structure. For instance, a top surface of the interconnect structures 800 can be substantially coplanar with a top surface of the contact level dielectric layer 620.

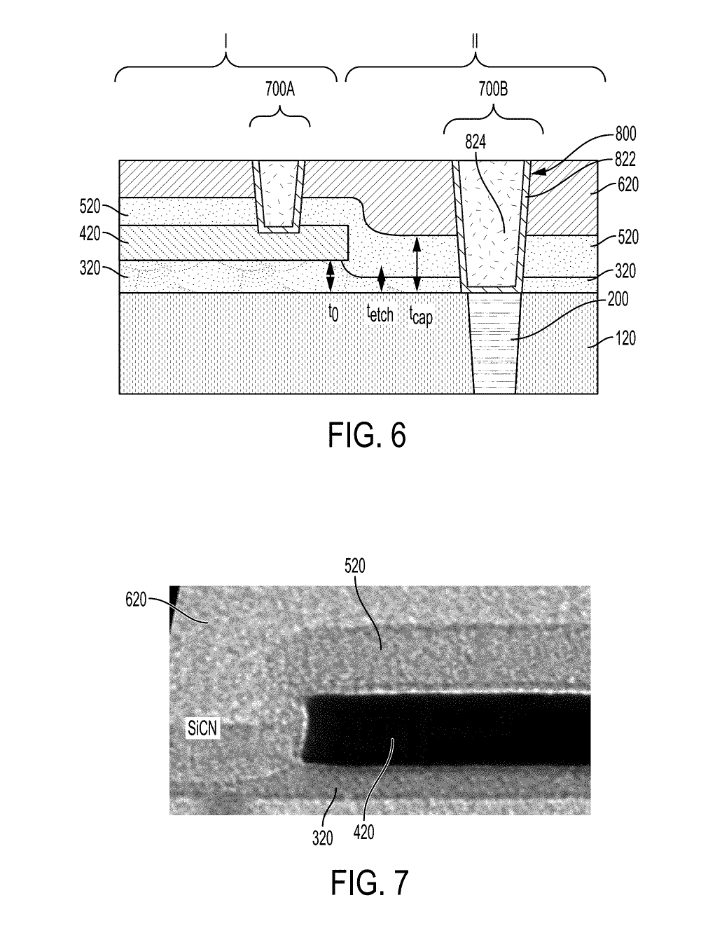

FIG. 6 schematically shows the patterned metal thin film 420 within a first region (I) of the device and partially etched capping layer 320 within a second region (II) of the device. A cross-sectional transmission electron microscope (TEM) micrograph is shown in FIG. 7, where capping layer 320 has an as-deposited thickness (t₀) beneath the metal thin film 420 (within first region (I)), and a post-etch thickness (t_{etch},t_{etch}≤t₀) laterally-adjacent to the metal thin film 420 within second region (II). In the illustrated embodiment, the as-deposited thickness (t₀) of the capping layer 320, i.e., beneath the patterned metal thin film 420, is about 5 to 10 nm, while after patterning the metal thin film 420, the thickness (t_{etch}) of the capping layer 320 not covered by the metal thin film is about 2.5 to 5 nm. In various embodiments, the post-etch thickness of the capping layer 320 adjacent to the patterned metal thin film 420 and disposed over interconnect structure 200 remains adequate to protect the interconnect structure 200.

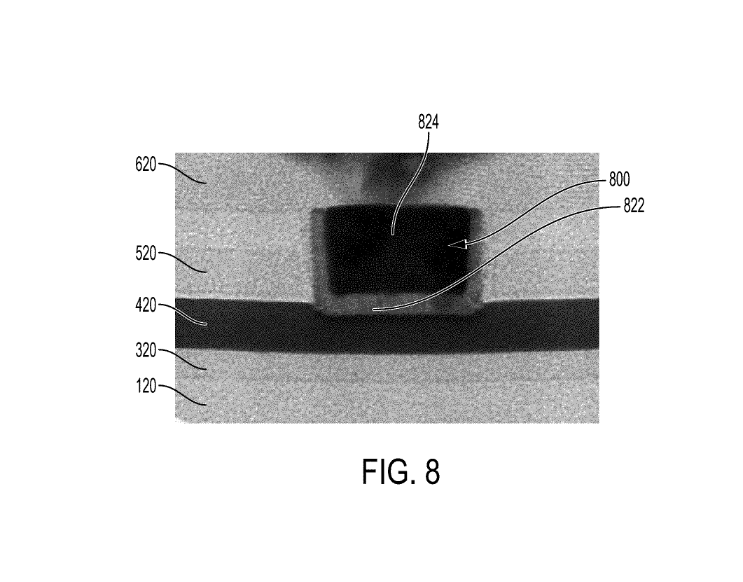

FIG. 8 is a TEM micrograph showing an interconnect structure 800 within the first region (I) of the device extending through contact level dielectric layer 620 and capping layer 520 and making contact with metal thin film 420. A robust contact is formed to the metal thin film 420 along both the bottom and sidewall surfaces of the interconnect structure 800. In FIG. 8, the via opening etch has removed less than 20% of the thickness of the metal thin film 420. In various embodiments, the via opening etch does not substantially etch the metal thin film. For instance, the via opening etch over the metal thin film 420, which accompanies the via opening etch over the interconnect structure 200, removes less than 50% of the thickness of the metal thin film, e.g., less than 5, 10, 20, 30, 40, or 50% of the thickness, including ranges between any of the foregoing values, which represents a significant improvement over the comparative structure and method.

According to various embodiments, during patterning and etching of the metal thin film 420, capping layer 320, which is disposed over interconnect structure 200, protects the interconnect structure 200. Capping layer 520 is configured to inhibit diffusion of metal atoms such as copper, and can serve as a diffusion barrier between metal-containing structures and neighboring dielectric layers to prevent metal atom diffusion into the dielectric layers.

The impact of the processing on the contact resistance of the patterned metal thin film was measured. Data corresponding to a comparative architecture include a relatively thick (20 nm) blanket SiCN capping layer 32. Excessive gouging of the metal thin film 42 results in a resistance increase of 12-25% relative to a baseline and concomitant degradation of the eFUSE critical dimension.

According to various embodiments, data for structures that include a first capping layer 320 (TS capping layer) below the metal thin film 420 and over the interconnect structure 200, and a second capping layer (RM capping layer) above the metal thin film exhibit an 8-10% decrease in the contact resistance compared with the baseline. For example, according to various embodiments, the contact resistance associated with the modified architecture can be improved by 5 to 20% with respect to comparative architectures.

As disclosed herein, the first capping layer 320 is disposed over the interconnect structure 200 that is laterally-displaced from the metal thin film. A further capping layer 520 is disposed over the metal thin film 420 and over the interconnect structure 200. In certain embodiments, the metal thin film is thus encapsulated by the capping layers 320, 520.

Contact etching of the capping layers 520, 320 over the interconnect structure 200 is accompanied by contact etching of the capping layer 520 over the metal thin film 420. Due to comparable average etch rates and thicknesses of the capping layers, the time to etch the capping layer over the interconnect structure and expose the interconnect structure is comparable to the time to etch the capping layer over the metal thin film. Thus, in contrast to the comparative structure where the etch time to expose the interconnect structure is significantly greater than the etch time to expose the metal thin film, which results in etching and concomitant gouging of the metal thin film, the etch time to expose the interconnect structure according to various embodiments is comparable to the etch time to expose the metal thin film. The disclosed process and corresponding structure obviate challenges in eFUSE programming by providing a robust and reliable contact.

As used herein, the singular forms “a,” “an” and “the” include plural referents unless the context clearly dictates otherwise. Thus, for example, reference to a “dielectric layer” includes examples having two or more such “dielectric layers” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a capping layer that comprises SiCN include embodiments where the capping layer consists essentially of SiCN and embodiments where the capping layer consists of SiCN.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A method of forming a semiconductor device, comprising:
forming a first dielectric layer over an exposed surface of an interconnect structure;
forming a patterned metal thin film laterally displaced from the interconnect structure;
forming a second dielectric layer over the patterned metal thin film and over the first dielectric layer above the interconnect structure;
etching a first via opening through the second dielectric layer to expose a top surface of the patterned metal thin film;
etching a second via opening through the second dielectric layer and the first dielectric layer to expose a top surface of the interconnect structure;
forming a first contact in the first via opening in electrical contact with the patterned metal thin film; and
forming a second contact in the second via opening in electrical contact with the interconnect structure, wherein a thickness and an etch rate of the second dielectric layer over the patterned metal thin film differs by less than 25% from a combined thickness and a combined etch rate of the first dielectric layer and the second dielectric layer over the interconnect structure.

2. The method according to claim 1, wherein the first via opening and the second via opening are etched simultaneously.

3. The method according to claim 1, wherein the first dielectric layer comprises a material selected from the group consisting of silicon nitride and silicon carbon nitride, and the second dielectric layer comprises a material selected from the group consisting of silicon nitride and silicon carbon nitride.

4. The method according to claim 1, wherein the first dielectric layer and the second dielectric layer each comprise silicon carbon nitride.

5. The method according to claim 1, wherein an average etch rate of the second dielectric layer over the patterned metal thin film is within 25% of an average etch rate of the second dielectric layer and the first dielectric layer over the interconnect structure.

6. The method according to claim 1, wherein an average etch time of the second dielectric layer to expose the patterned metal thin film is within 25% of an average etch time of the second dielectric layer and the first dielectric layer to expose the interconnect structure.

7. The method according to claim 1, wherein the patterned metal thin film is formed over a portion of the first dielectric layer.

8. The method according to claim 1, wherein a portion of the second dielectric layer is formed directly over the patterned metal thin film.

9. The method according to claim 1, wherein a portion of the second dielectric layer is formed directly over the first dielectric layer.

10. The method according to claim 1, wherein etching the first via opening etches less than 50% of a thickness of the patterned metal thin film within the first via opening.

11. The method according to claim 1, further comprising forming a contact level dielectric layer over the first dielectric layer and over the second dielectric layer prior to etching the first via opening and the second via opening, wherein the contact level dielectric comprises silicon dioxide.

12. A semiconductor device comprising:
a first dielectric layer disposed over an exposed surface of an interconnect structure;
a patterned metal thin film laterally displaced from the interconnect structure;
a second dielectric layer disposed over the patterned metal thin film and over an exposed surface of the first dielectric layer laterally displaced from the patterned metal thin film;
a first contact extending through the second dielectric layer and in electrical contact with the patterned metal thin film; and
a second contact extending through the second dielectric layer and the first dielectric layer and in electrical contact with the interconnect structure, wherein a thickness of the second dielectric layer over the patterned metal thin film differs by less than 25% from a combined thickness of the first dielectric layer and the second dielectric layer over the interconnect structure.

13. The semiconductor device according to claim 12, wherein the first dielectric layer comprises a material selected from the group consisting of silicon nitride and silicon carbon nitride, and the second dielectric layer comprises a material selected from the group consisting of silicon nitride and silicon carbon nitride.

14. The semiconductor device according to claim 12, wherein the first dielectric layer and the second dielectric layer each comprise silicon carbon nitride.

15. The semiconductor device according to claim 12, wherein the patterned metal thin film comprises tungsten silicide.

16. The semiconductor device according to claim 12, wherein a bottom surface and a sidewall surface of the first contact each directly contact the patterned metal thin film.

17. The semiconductor device according to claim 12, wherein the patterned metal thin film is disposed over a portion of the first dielectric layer.

18. The semiconductor device according to claim 12, wherein the second dielectric layer is disposed directly over the patterned metal thin film.

19. The semiconductor device according to claim 12, wherein the patterned metal thin film forms an eFUSE or a precision resistor.

20. The semiconductor device according to claim 12, wherein the first contact extends through less than 50% of a thickness of the patterned metal thin film.
